(19) United States
(12) Patent Application Publication
(10) Pub. No.: US 2019/0131588 A1
(43) Pub. Date: May 2, 2019

(54) ELECTRONIC DEVICE AND METHOD OF MANUFACTURING ELECTRONIC DEVICE

(71) Applicant: JOLED INC., Tokyo (JP)

(72) Inventors: Shina KURIKI, Tokyo (JP); Tsutomu MORI, Tokyo (JP); Naoto ODA, Tokyo (JP)

(21) Appl. No.: 16/154,725

(22) Filed: Oct. 9, 2018

(30) Foreign Application Priority Data
Oct. 27, 2017 (JP) 2017-207944

(51) Int. Cl. H01L 51/56; H01L 27/32; H01L 51/52

(52) U.S. Cl. CPC H01L 51/56; H01L 27/3276; H01L 51/5221; H01L 51/5206; H01L 51/5253

(57) ABSTRACT

An electronic device includes a substrate, a first electrode, a second electrode, and a protective film. The substrate includes an element region. The first electrode is provided in the element region on the substrate. The second electrode faces the first electrode and is provided across from the element region to an outside of the element region. The second electrode includes a first electrically conductive film. The protective film covers the first electrically conductive film. The protective film has an end part under which the first electrically conductive film is disposed.

### CROSS REFERENCE TO RELATED APPLICATIONS

This application claims the benefit of Japanese Priority Patent Application JP 2017-207944 filed on Oct. 27, 2017, the entire contents of which are incorporated herein by reference.

### BACKGROUND

The technology relates to an electronic device including an electrode on a substrate, and to a method of manufacturing the electronic device.

An organic electroluminescent (EL) display unit includes a plurality of organic EL elements in a display region of a substrate. The organic EL elements each include an organic layer, for example, between a first electrode and a second electrode. For example, reference is made to Japanese Unexamined Patent Application Publication No. 2001-43971.

### SUMMARY

It has been desired to reduce manufacturing costs of an electronic device such as an organic EL display unit.

It is desirable to provide an electronic device that makes it possible to reduce manufacturing costs, and a method of manufacturing the electronic device.

A method of manufacturing an electronic device according to an embodiment of the technology includes: forming a first electrode in an element region on a substrate; forming a first electrically conductive film that faces the first electrode and is provided across from the element region to an outside of the element region; and forming a protective film that covers the first electrically conductive film; etching a portion of the first electrically conductive film provided outside the element region after the formation of the protective film; and forming a second electrode including the etched first electrically conductive film.

An electronic device according to an embodiment of the technology includes a substrate, a first electrode, a second electrode, and a protective film. The substrate includes an element region. The first electrode is provided in the element region on the substrate. The second electrode faces the first electrode and is provided across from the element region to an outside of the element region. The second electrode includes a first electrically conductive film. The protective film covers the first electrically conductive film. The protective film has an end part under which the first electrically conductive film is disposed.

### BRIEF DESCRIPTION OF THE DRAWINGS

The accompanying drawings are included to provide a further understanding of the technology, and are incorporated in and constitute a part of this specification. The drawings illustrate example embodiments and, together with the specification, serve to explain the principles of the technology.

FIG. 1 is a schematic plan view of an outline configuration of a display unit according to one embodiment of the disclosure.

FIG. 2 is a block diagram illustrating an overall configuration of the display unit illustrated in FIG. 1.

FIG. 3 is a schematic view of arrangement of pixels illustrated in FIG. 2.

FIG. 4 is schematic view of a cross-sectional configuration taken along line IV-IV′ illustrated in FIG. 1.

FIG. 5 is a schematic plan view of a configuration of a planarizing film illustrated in FIG. 4.

FIG. 6 is a flowchart illustrating, in an order of processes, a method of manufacturing the display unit illustrated in FIG. 4.

FIG. 7A is a schematic cross-sectional view illustrating one process of the method of manufacturing the display unit illustrated in FIG. 6.

FIG. 7B is a schematic cross-sectional view illustrating a process subsequent to FIG. 7A.

FIG. 7C is a schematic cross-sectional view illustrating a process subsequent to FIG. 7B.

FIG. 7D is a schematic cross-sectional view illustrating a process subsequent to FIG. 7C.

FIG. 8 is a flowchart illustrating, in an order of processes, a method of manufacturing a display unit according to a comparative example.

FIG. 9 describes a process of forming a second electrode illustrated in FIG. 8.

FIG. 10A is a schematic cross-sectional view illustrating one process of the method of manufacturing the display unit illustrated in FIG. 8.

FIG. 10B is a schematic cross-sectional view illustrating a process subsequent to FIG. 10A.

FIG. 11 is a flowchart illustrating, in an order of processes, a method of manufacturing a display unit according to Modification Example 1.

FIG. 12A is a schematic cross-sectional view illustrating one process of the method of manufacturing the display unit illustrated in FIG. 11.

FIG. 12B is a schematic cross-sectional view illustrating a process subsequent to FIG. 12A.

FIG. 13 is a flowchart illustrating, in an order of processes, a method of manufacturing a display unit according to Modification Example 2.

FIG. 14 is a schematic view of a cross-sectional configuration of a display unit manufactured by the method illustrated in FIG. 13.

FIG. 15 is a block diagram illustrating an example outline configuration of any of the display units illustrated in figures such as FIG. 1.

FIG. 16 is a block diagram illustrating an example outline configuration of an imaging unit as an electronic device of the technology.

FIG. 17 is a block diagram illustrating an example electronic apparatus to which the display unit illustrated in FIG. 15 or the imaging unit illustrated in FIG. 16 is applied.

### DETAILED DESCRIPTION

In the following, some example embodiments of the technology are described in detail with reference to the accompanying drawings. Note that the following description is directed to illustrative examples of the technology and not to be construed as limiting to the technology. Factors including, without limitation, numerical values, shapes, materials, components, positions of the components, and how the components are coupled to each other are illustrative only and not to be construed as limiting to the technology. Further, elements in the following example embodiments which are not recited in a most-generic independent claim of the technology are optional and may be provided on an as-needed basis. The drawings are schematic and are not intended to be drawn to scale. Note that the like elements are denoted with the same reference numerals, and any redundant description thereof will not be described in detail. Note that the description is given in the following order.

1. Example Embodiment (A display unit in which a second electrode is disposed under an end part of a protective film)

2. Modification Example 1 (An example in which a protective film is formed using a mask)

3. Modification Example 2 (An example in which a second electrode having a stacked structure is provided)

4. Application Example

### Example Embodiment

### [Configuration]

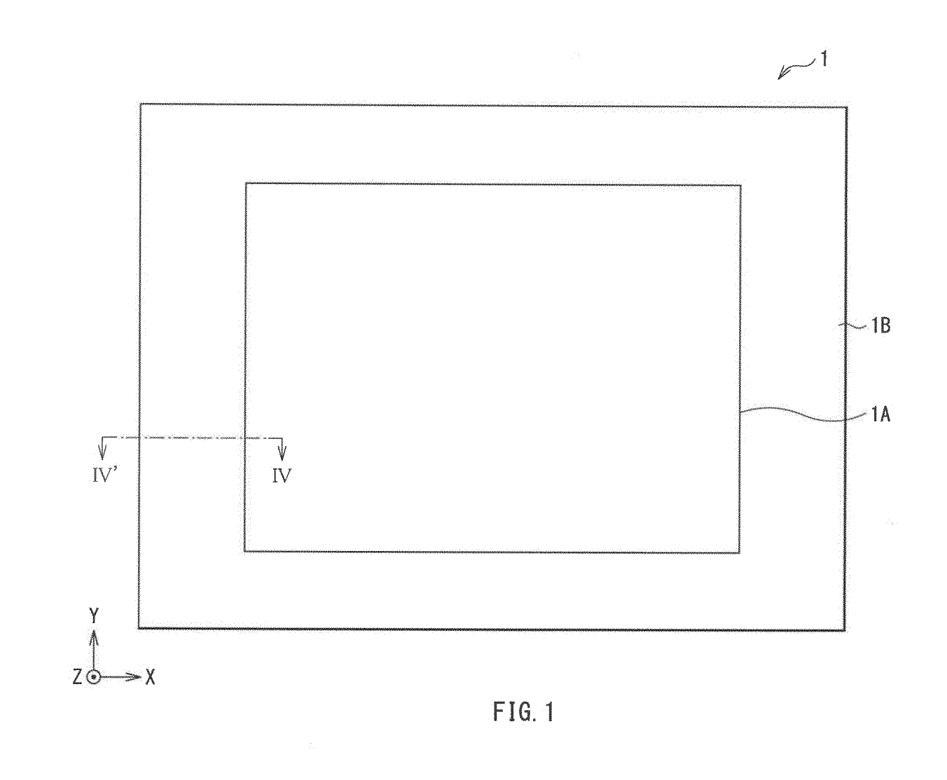

FIG. 1 schematically illustrates an overall configuration of a display unit (e.g., a display unit 1) according to an embodiment of the disclosure. The display unit may be, for example, an organic EL display including an organic electroluminescent element. The display unit 1 may be a top emission display unit which emits, for example, light of any of R (red), G (green), and B (blue) from top face side. The display unit 1 may include a display region 1A at the middle and a peripheral region 1B outside the display region 1A. The display region 1A corresponds to a specific but non-limiting example of an “element region” according to one embodiment of the disclosure. The display region 1A may have a quadrangular shape, for example. The peripheral region 1B may be provided in a bezel shape in a manner to surround the display region 1A.

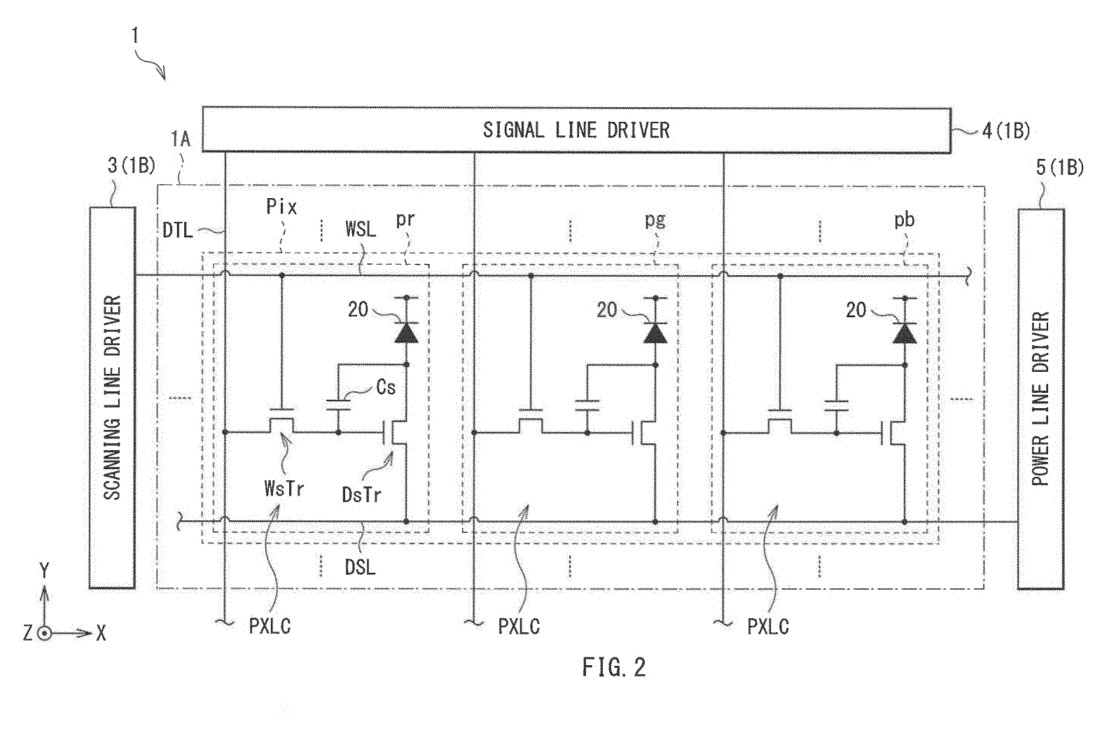

FIG. 2 illustrates an example of a configuration of each of the display region 1A and the peripheral region 1B. The display region 1A may include a plurality of pixels pr, pg, and pb that are arranged two-dimensionally. An image may be displayed on the display region 1A, by means of an active matrix scheme, for example, on the basis of an image signal inputted from an external device. There may be provided, in the peripheral region 1B, for example, a circuit section (i.e., a scanning line driver 3, a signal line driver 4, and a power line driver 5) that drives the display region 1A. There may be provided, across from the display region 1A to the peripheral region 1B, for example, a plurality of scanning lines WSL each extending in a row direction of pixel arrangement, a plurality of signal lines DTL each extending in a column direction, and a plurality of power lines DSL each extending in the row direction. The pixels pr, pg, and pb may be each coupled to the scanning line driver 3, the signal line driver 4, and the power line driver 5 via, respectively, the scanning line WSL, the signal line DTL, and the power line DSL. The pixels pr, pg, and pb may each correspond to a subpixel, for example. A set of the pixels pr, pg, and pb may configure one pixel, i.e., a pixel Pix.

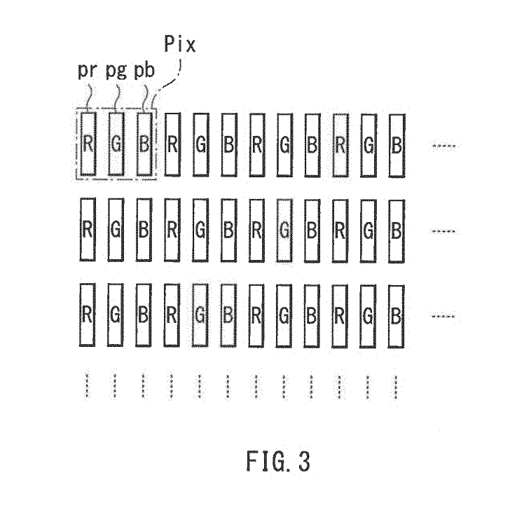

FIG. 3 illustrates an example of a planar configuration of the pixel Pix, i.e., the pixels pr, pg, and pb illustrated in FIG. 2. The pixels pr, pg, and pb may each have a rectangular surface shape, for example, and may be arranged in a stripe shape as a whole. Pixels of the same emission color may be arranged in a direction (i.e., a column direction in FIG. 3) along a long side of the rectangular shape of each of the pixels pr, pg, and pb. The pixel pr may display a red color (R), for example. The pixel pg may display a green color (G), for example. The pixel pb may display a blue color (B), for example. The pixels pr, pg, and pb may each include a pixel circuit PXLC that includes an organic EL element 20, as illustrated in FIG. 2.

Hereinafter, the pixels pr, pg, and pb are each referred to as a “pixel P” for description in a case where no particular distinction is necessary.

The pixel circuit PXLC may control light emission and light extinction in each of the pixels pr, pg, and pb. The pixel circuit PXLC may include the organic EL element (i.e., a display element) 20, a storage capacitor Cs, a switching transistor WsTr, and a driving transistor DsTr, for example. Note that, in this example, a circuit configuration of 2Tr1C is exemplified as the pixel circuit PXLC; however, the configuration of the pixel circuit PXLC is not limited thereto. The pixel circuit PXLC may have a circuit configuration in which components such as various capacitors and transistors are further added to the 2Tr1C circuit.

The switching transistor WsTr may control application of an image signal, i.e., a signal voltage to a gate electrode of the driving transistor DsTr. In a specific but non-limiting example, the switching transistor WsTr may sample a voltage, i.e. a signal voltage, of the signal line DTL in response to a voltage applied to the scanning line WSL, and may write the signal voltage into the gate electrode of the driving transistor DsTr. The driving transistor DsTr may be coupled in series to the organic EL element 20, and may control a current that flows to the organic EL element 20 in accordance with magnitude of the signal voltage sampled by the switching transistor WsTr. The driving transistor DsTr and the switching transistor WsTr may be each configured by an n-channel MOS or p-channel MOS thin film transistor (TFT), for example. The driving transistor DsTr and the switching transistor WsTr may be each a single-gate transistor or a dual-gate transistor. The storage capacitor Cs may store a predetermined voltage between the gate electrode and a source electrode of the driving transistor DsTr.

The switching transistor WsTr has a gate electrode that may be coupled to the scanning line WSL. The switching transistor WsTr has a source electrode and a drain electrode; one electrode thereof may be coupled to the signal line DTL, and the other electrode thereof may be coupled to the gate electrode of the driving transistor DsTr. The driving transistor DsTr has the source electrode and a drain electrode; one electrode thereof may be coupled to the power line DSL, and the other electrode thereof may be coupled to an anode, i.e., a first electrode 21 described later of the organic EL element 20. The storage capacitor Cs may be provided between the gate electrode of the driving transistor DsTr and an electrode on side of the organic EL element 20.

The scanning line WSL may supply a selection pulse to each of the pixels P. The selection pulse may be used to select, on a row basis, a plurality of pixels P arranged in the display region 1A. The scanning line WSL may be coupled to an unillustrated output end of the scanning line driver 3 and to the gate electrode of the switching transistor WsTr described later. The signal line DTL may supply, to each of the pixels P, a signal pulse (i.e., a signal electric potential Vsig and a reference electric potential Vofs) based on the image signal. The signal line DTL may be coupled to an unillustrated output end of the signal line driver 4 and to the source electrode or the drain electrode of the switching transistor WsTr described later. The power line DSL may supply, to each of the pixels P, a fixed electric potential (Vcc) as power. The power line DSL may be coupled to an unillustrated output end of the power line driver 5 and to the source electrode or the drain electrode of the driving transistor DsTr described later. Note that the organic EL element 20 has a cathode, i.e., a second electrode 24 described later that may be coupled to a common electric potential line, i.e., a cathode line.

The scanning line driver 3 may output a predetermined selection pulse to each of the scanning lines WSL line-sequentially to thereby cause each of the pixels P to execute each of operations such as anode reset, Vth compensation, writing of the signal electric potential Vsig, mobility compensation, and light emission operation, for example, at a predetermined timing. The signal line driver 4 may generate an analog image signal corresponding to a digital image signal inputted from an external device, and may output the generated analog image signal to each of the signal lines DTL. The power line driver 5 may output a fixed electric potential to each of the power lines DSL. The scanning line driver 3, the signal line driver 4, and the power line driver 5 may be controlled to operate in conjunction with one another, on the basis of a timing control signal outputted by an unillustrated timing controller. A digital image signal inputted from the external device may be compensated by an unillustrated image signal receiver. Thereafter, the resultant digital image signal may be inputted to the signal line driver 4.

Description is given below of a specific but non-limiting configuration of the display unit 1.

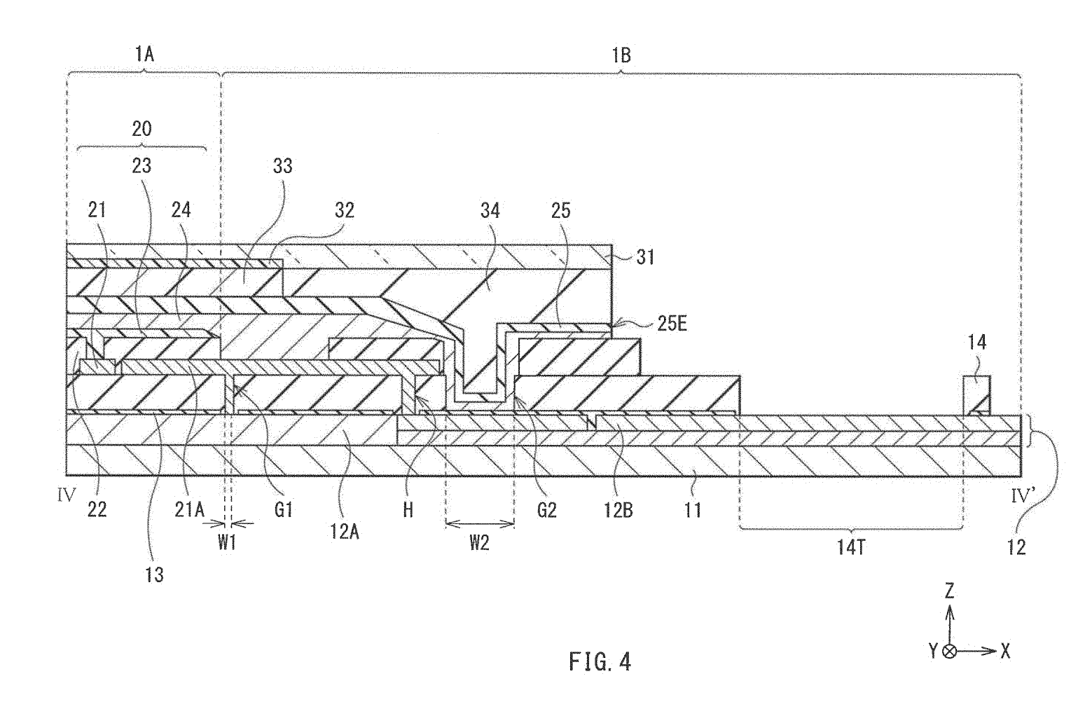

FIG. 4 schematically illustrates a cross-sectional configuration of the display unit 1 across from the display region 1A to the peripheral region 1B, and corresponds to a cross-sectional configuration taken along line IV-IV′ illustrated in FIG. 1. In the display unit 1, a plurality of organic EL elements 20 may be sealed between a first substrate 11 and a second substrate 31 that face each other. The first substrate 11 corresponds to a specific but non-limiting example of a “substrate” according to one embodiment of the disclosure. On the first substrate 11, there may be provided a wiring layer 12, a passivation film 13, and a planarizing film 14, in this order. The organic EL element 20 may be provided on the planarizing film 14, and may include, from side of the planarizing film 14, the first electrode 21, an organic layer 23, and a second electrode 24. The organic layer 23 corresponds to a specific but non-limiting example of a “functional layer” according to one embodiment of the disclosure. An element separation film 22 may be provided between adjacent organic EL elements 20. A protective film 25, for example, may be provided on the organic EL elements 20. The second substrate 31 may be joined onto the protective film 25 with a filling layer 33 interposed therebetween. A sealing section 34 may be provided on the periphery of the second substrate 31. The organic EL element 20 may be sealed between the first substrate 11 and the second substrate 31. A color filter layer 32, for example, may be provided on a surface, of the second substrate 31, that faces the first substrate 11.

The first substrate 11 may be configured, for example, by glass, quartz, silicone, a resin material, or a metal plate. Non-limiting examples of the resin material may include polyethylene terephthalate (PET), polyimide (PI), polycarbonate (PC), and polyethylene naphthalate (PEN).

The wiring layer 12 on the first substrate 11 may include, mainly, a drive circuit section 12A and a peripheral circuit section 12B, for example. The drive circuit section 12A may be provided in the display region 1A, and the peripheral circuit section 12B may be provided in the peripheral region 1B. For example, the pixel circuit PXLC illustrated in FIG. 2 may be provided in the drive circuit section 12A, and the scanning line driver 3, the signal line driver 4, and the power line driver 5 may be each provided in the peripheral circuit section 12B. The scanning line WSL, the signal line DTL, and the power line DSL may be each provided in the wiring layer 12, and may each extend from the display region 1A to the peripheral region 1B.

An undercoat (UC) film may be provided between the first substrate 11 and the wiring layer 12. The UC film may prevent movement of, for example, a substance such as a sodium ion from the first substrate 11 to an upper layer. The UC film may be configured by an insulating material such as a silicon nitride (SiN) film and a silicon oxide (SiO₂) film.

The passivation film 13 that covers the wiring layer 12 may be provided across the display region 1A and the peripheral region 1B. The passivation film 13 may be configured, for example, by a silicon oxide (SiO₂) film having a thickness of 200 nm. For the passivation film 13, for example, a silicon nitride (SiN) film, a silicon oxynitride (SiON) film, a titanium oxide (TiO₂) film, or an aluminum oxide (Al₂O₃) film may be used. In an alternative embodiment, a stack of these films may also be used for the passivation film 13.

The planarizing film 14 may cover the wiring layer 12 with the passivation film 13 interposed therebetween. The planarizing film 14 may be provided across the display region 1A and the peripheral region 1B. A first groove G1 and a second groove G2 may be provided inside the peripheral region 1B in the planarizing film 14. The first groove G1 may be provided near the periphery of the display region 1A, and may have a width W1 (a size along an X-direction in FIG. 4, for example). The second groove G2 may be provided outside the first groove G1, and may have a width of W2. In an example embodiment, the width W1 of the first groove G1 may be 10 μm or more, and may be in a range from 10 μm to 2,000 μm, for example. In an example embodiment, the width W2 of the second groove G2 may be 10 μm or more, and may be in a range from 10 μm to 2,000 μm, for example. The first groove G1 and the second groove G2 may each penetrate the planarizing film 14, for example. The first groove G1 may penetrate the planarizing film 14 and the passivation film 13 to reach the wiring layer 12. The second groove G2 may penetrate the planarizing film 14, and the passivation film 13 may be exposed from the planarizing film 14 in the second groove G2.

FIG. 5 schematically illustrates a planar configuration of the first groove G1 and the second groove G2. The first groove G1 provided in the peripheral region 1B may surround the display region 1A along the periphery of the display region 1A, and the first groove G1 may be surrounded by the second groove G2. The first groove G1 and the second groove G2 may each have a quadrangular planar shape, for example. Providing the first groove G1 and the second groove G2 in the planarizing film 14 having a high moisture permeability makes it possible to suppress moisture ingress from the peripheral region 1B outside the second groove G2 into the display region 1A due to the planarizing film 14. In the display unit 1, the provision of the second groove G2 and the first groove G1 disposed at a location closer to the display region 1A than the second groove G2 suppresses moisture ingress due to the second electrode 24.

There may be provided, in the peripheral region 1B outside the second groove G2, a terminal region 14T where the planarizing film 14 and the passivation film 13 are removed. In the terminal region 14T, the wiring layer 12 (i.e., the peripheral circuit section 12B) may be exposed. An external wiring line may be coupled to the peripheral circuit section 12B via the terminal region 14T, for example. As the planarizing film 14, a polyimide resin film having a thickness of 3,000 nm, for example, may be used. As the planarizing film 14, a resin such as an epoxy resin, a novolak resin, and an acrylic resin may also be used.

The organic EL element 20 may be disposed in the display region 1A on the planarizing film 14 for each of the pixels pr, pg, and pb. A plurality of first electrodes 21 of the organic EL element 20 may be disposed on the planarizing film 14. The first electrodes 21 may be separated from one another.

The first electrode 21 may be a reflective electrode that serves as an anode, for example, and may be provided for each of the pixels P. Non-limiting examples of a constituent material of the first electrode 21 may include a simple substance and an alloy of a metal element such as aluminum (Al), chromium, gold (Au), platinum (Pt), nickel (Ni), copper (Cu), tungsten, and silver (Ag). Further, the first electrode 21 may include a stacked film of a metal film and an electrically conductive material (e.g., a transparent electrically conductive film) having light-transmissivity. The metal film may be made of a simple substance or an alloy of the above-mentioned metal elements. Non-limiting examples of the transparent electrically conductive film may include indium-tin oxide (ITO), indium-zinc oxide (IZO), and a zinc oxide (ZnO)-based material. Non-limiting examples of the zinc oxide-based material may include aluminum (Al)-doped zinc oxide (AZO) and gallium (Ga)-doped zinc oxide (GZO).

A wiring line 21A, for example, may be provided in the same layer as the first electrode 21. The wiring line 21A may be embedded in the first groove G1, and may be electrically coupled to a wiring line of the wiring layer 12 via a contact hole H provided in the planarizing film 14.

The element separation film 22 may cover the plurality of first electrodes 21, and may be provided across from a surface of each first electrode 21 to a surface of an adjacent first electrode 21. The element separation film 22 may have an opening that faces each first electrode 21. The first electrode 21 may be exposed from the element separation film 22 in the opening, and the organic layer 23 may be disposed on the exposed first electrode 21. The element separation film 22 may define a light-emitting region of each of the pixels P, and may ensure an insulating property between the first electrode 21 and the second electrode 24. The element separation film 22 may serve as a so-called partition wall in a case where the organic layer 23 is formed by means of a wet process.

The element separation film 22 may be provided, for example, in the peripheral region 1B, and may be disposed at a location that does not block the first groove G1 and the second groove G2 of the planarizing film 14. In other words, in a plan view (e.g., an X-Y plane in FIG. 4), the element separation film 22 may be provided with a groove at each of locations that overlap the first groove G1 and the second groove G2. The width of the groove of the element separation film 22 may be larger than each of the width W1 of the first groove G1 and the width W2 of the second groove G2. In the peripheral region 1B, the element separation film 22 may be provided inside the terminal region 14T (i.e., on side of the display region 1A). To serve as the partition wall as described above, the element separation film 22 may include, for example, a photosensitive resin such as an acrylic resin, a polyimide resin, a fluorine resin, a silicon resin, a fluorine polymer, a silicon polymer, a novolak resin, an epoxy resin, and a norbornene resin. In an alternative embodiment, any of these resin materials with a pigment dispersed therein may also be used. Further, for example, an inorganic material such as silicon oxide, silicon nitride, and silicon oxynitride may also be used for the element separation film 22.

The organic layer 23 including an organic light-emitting material may include, for example, a hole injection layer, a hole transport layer, a light-emitting layer, an electron transport layer, and an electron injection layer, in this order from side of the first electrode 21. The organic layer 23 may be provided in the opening of the element separation film 22 for each of the pixels pr, pg, and pb. In an alternative embodiment, the organic layer 23 may be provided in common for the pixels pr, pg, and pb. The light-emitting layers of the respective pixels pr, pg, and pb may have different colors. For example, the light-emitting layer of the pixel pr, the light-emitting layer of the pixel pg, and the light-emitting layer of the pixel pb generate a red color, a green color, and a blue color, respectively. In an alternative embodiment, all of the light-emitting layers of the pixels pr, pg, and pb may generate the same color. For example, all of the light-emitting layers of the pixels pr, pg, and pb may generate a white color.

The hole injection layer may suppress or prevent leakage, and may be configured by hexaazatriphenylene (HAT), for example. The hole injection layer may have a thickness of 1 nm to 20 nm, for example. The hole transport layer may be configured, for example, by α-NPD[N,N′-di(1-naphthyl)-N,N′-diphenyl[1,1′-biphenyl]-4,4′-diamine]. The hole transport layer may have a thickness of 15 nm to 100 nm, for example.

The light-emitting layer may be configured to emit light of a predetermined color by means of coupling between holes and electrons. The light-emitting layer may have a thickness of 5 nm to 50 nm, for example. The light-emitting layer that emits light in a red wavelength region may be configured by rubrene doped with a pyrromethene-boron complex, for example. At this occasion, rubrene may be used as a host material. The light-emitting layer that emits light in a green wavelength region may be configured by Alq³(trisquinolinol-aluminum complex), for example. The light-emitting layer that emits light in a blue wavelength region may be configured by ADN(9,10-di(2-naphthyl)anthracene) doped with a diaminochrysene derivative, for example. At this occasion, ADN is vapor-deposited as a host material having a thickness of 20 nm, for example, on the hole transport layer. The diaminochrysene derivative may be doped as a dopant material at a relative film thickness ratio of 5%.

The electron transport layer may be configured by BCP(2,9-dimethyl-4,7-diphenyl-1,10-phenanthroline. The electron transport layer may have a thickness of 15 nm to 200 nm, for example. The electron injection layer may be configured by lithium fluoride (LiF), for example. The electron injection layer may have a thickness of 15 nm to 270 nm, for example.

The second electrode 24 may serve as a cathode, for example, and may face the first electrode 21 with the organic layer 23 interposed therebetween. The second electrode 24 may be provided, as an electrode common to all of the pixels P, across the entire surface of the display region 1A, and may extend from the display region 1A to the peripheral region 1B. In the peripheral region 1B, the second electrode 24 may extend to the outside of the second groove G2, and may be embedded in the second groove G2. An end part of the second electrode 24 may be provided inside the terminal region 14T. As used herein, the end part of the second electrode 24 refers to a part including an end surface of the second electrode 24. The second electrode 24 may be configured, for example, by a light-transmissive electrically conductive material (e.g., a transparent electrically conductive film). The transparent electrically conductive film that configures the second electrode 24 may include metal or a metal oxide, for example. In a specific but non-limiting example, the second electrode 24 may include silver (Ag), aluminum (Al), zinc oxide (ZnO), indium(III) oxide (In₂O₃), stannic oxide (SnO₂), aluminum oxide (Al₂O₃), gallium oxide (Ga₂O₃), titanium oxide (TiO₂), niobium oxide (Nb₂O₅), or silicon oxide (SiO₂). The second electrode 24 may have a stacked structure of a plurality of electrically conductive films, as described later in Modification Example 2.

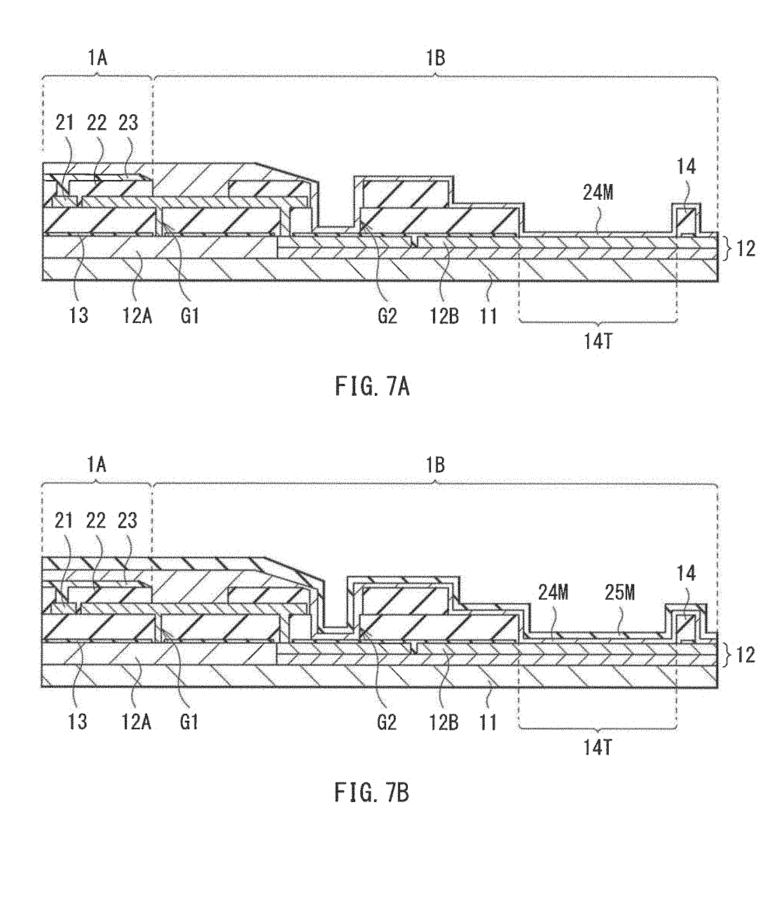

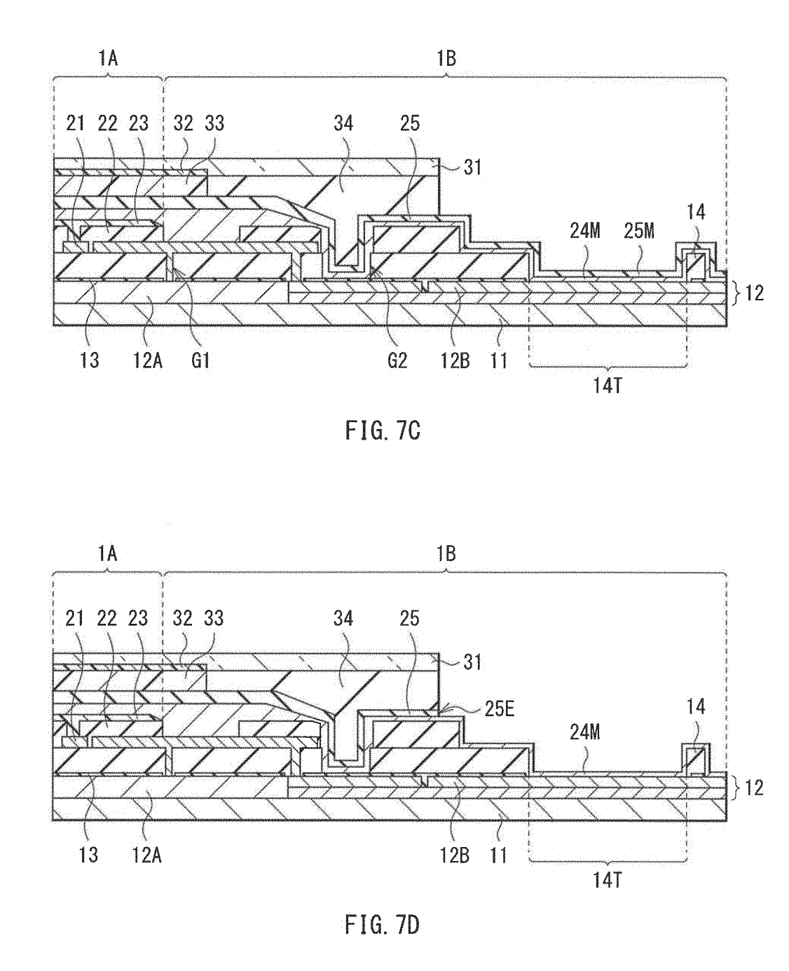

In the present example embodiment, the second electrode 24 may be formed by etching an electrically conductive film (i.e., an electrically conductive film 24M in FIG. 7A) having been formed without using an area mask. This makes it possible to reduce a cost caused by the use of the area mask, although the detail is described later.

The second electrode 24 may be etched, for example, using the protective film 25 as a mask. Accordingly, the second electrode 24 may have substantially the same planar shape as that of the protective film 25, and the end part of the second electrode 24 may be provided at a location overlapped by an end part 25E of the protective film 25 in a plan view (e.g., the X-Y plane in FIG. 4). In other words, the second electrode 24 may be disposed under the end part 25E of the protective film 25, and the end surface of the second electrode 24 may be exposed from the protective film 25. There is a conceivable possibility of moisture ingress from the end surface of the second electrode 24 exposed from the protective film 25. However, because of higher moisture permeability of the planarizing film 14 than that of the second electrode 24, the provision of the first groove G1 and the second groove G2 in the planarizing film 14 effectively suppresses the moisture ingress. It is confirmed, in moisture resistance reliability evaluation, that there is no lowering of reliability due to the exposure of the end surface of the second electrode 24. The end part of the second electrode 24 may be provided at a location substantially overlapped by the end part 25E of the protective film 25 in a plan view. However, the end part of the second electrode 24 may be disposed in a slightly shifted manner due to factors such as manufacturing error. For example, an electrically conductive film (i.e., the electrically conductive film 24M in FIG. 7A described later) having a thickness of 200 nm may be formed, and thereafter the electrically conductive film may be etched using a wet etching method. The end part of the second electrode 24 thus formed may be disposed about 0.5 μm inside, in some cases, from the location where the end part of the second electrode 24 is overlapped by the end part 25E of the protective film in a plan view.

Similarly to the second electrode 24, the protective film 25 that covers the second electrode 24 may be provided across the entire surface of the display region 1A, and may extend from the display region 1A to the peripheral region 1B. The end part 25E of the protective film 25 may be provided inside the terminal region 14T, in the peripheral region 1B. The protective film 25 (i.e., the end part 25E) may have a quadrangular planar shape, for example. The protective film 25 may be configured, for example, by silicon oxide (SiO₂), silicon nitride (SiN), silicon oxynitride (SiON), titanium oxide (TiO₂), or aluminum oxide (Al₂O₃). The protective film 25 may serve to suppress or prevent moisture ingress into the organic EL element 20 and suppresses or prevents variation in characteristics such as light emission efficiency.

The filling layer 33 may join the protective film 25 and the second substrate 31 together, and may seal the organic EL element 20. The filling layer 33 may be provided across a surface on the protective film 25. Non-limiting examples of a material of the filling layer 33 may include an acrylic resin, a polyimide resin, a fluorine resin, a silicon resin, a fluorine polymer, a silicon polymer, a novolak resin, an epoxy resin, and a norbornene resin. In an alternative embodiment, any of these resin materials with a pigment dispersed therein may also be used.

The sealing section 34 may be provided in the peripheral region 1B outside the filling layer 33. The sealing section 34 may be provided in a ring shape to surround the display region 1A, and may be disposed on the periphery of the second substrate 31. The sealing section 34 may seal, between the first substrate 11 and the second substrate 31, the components provided therebetween, together with the organic EL element 20. The sealing section 34 may be configured, for example, by a resin material such as an epoxy resin and an acrylic resin.

A color filter layer 32 may include a red filter, a green filter, and a blue filter, for example. The color filter layer 32 may be provided, for example, on a surface of the second substrate 31. For example, the color filter layer 32 may be provided on a surface on side of the filling layer 33. The red filter, the green filter, and the blue filter may be provided in regions facing the organic EL elements 20 for the pixels pr, pg, and pb, respectively. These red filters, green filters, and blue filters may be each configured by a resin with a pigment mixed therein.

A black matrix layer may also be provided in a region between the above-described red filter, green filter, and blue filter, i.e., in a region between pixels. The black matrix layer may be configured, for example, by a resin film with a black colorant mixed therein, or by a thin film filter utilizing interference of a thin film. The thin film filter may have a configuration in which, for example, one or more thin films configured by a material such as metal, a metal nitride, and a metal oxide are stacked to attenuate light by utilizing the interference of a thin film. Specific but non-limiting examples of the thin film filter may include a filter in which chromium (Cr) and chromium(III) oxide (Cr₂O₃) are stacked alternately.

The second substrate 31, together with the filling layer 33, may seal the organic EL element 20. The second substrate 31 may be configured, for example, by a material such as glass or plastic that is transparent to light generated in the organic EL element 20.

### [Manufacturing Method]

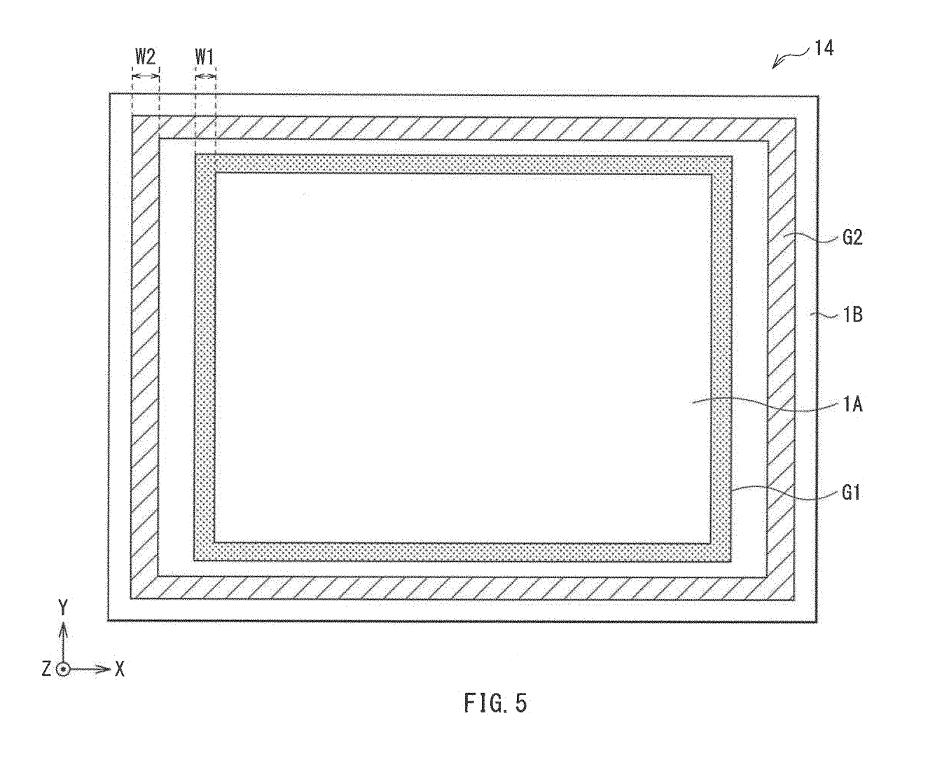

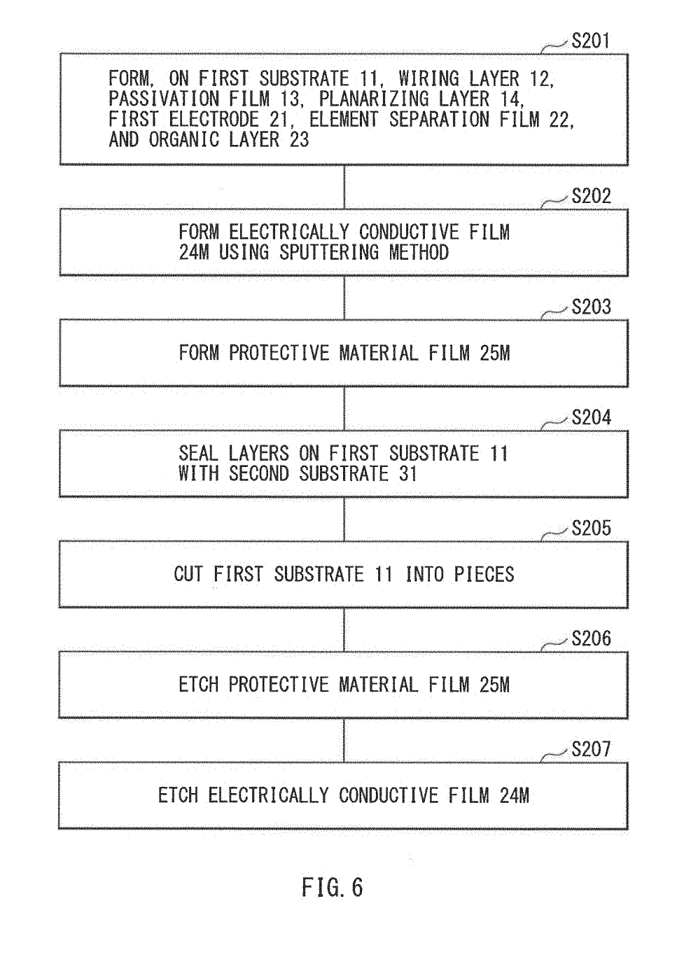

Such a display unit 1 may be manufactured, for example, through processes illustrated in FIG. 6. FIGS. 7A to 7D illustrate, in order, manufacturing processes of the display unit 1.

First, the wiring layer 12, the passivation film 13, the planarizing film 14, the first electrode 21, the element separation film 22, and the organic layer 23 may be formed in this order on the first substrate 11 (step S201). For example, this step S201 may be performed as follows.

First, the wiring layer 12 may be formed on the first substrate 11. Next, a chemical vapor deposition (CVD) method may be used to form a silicon oxide film to cover the wiring layer 12. This allows the passivation film 13 to be formed. Next, an organic insulating material having photosensitivity may be subjected to a spin-coating method or a slit-coating method, for example, to thereby form the planarizing film 14. Subsequently, exposure, development, and a firing treatment may be performed to thereby form, in the planarizing film 14, the first groove G1, the second groove G2, a contact hole reaching the wiring layer 12, and the terminal region 14T.

Thereafter, the first electrode 21 may be formed on the planarizing film 14. An electrically conductive material may be subjected to a sputtering method, for example, in a manner to fill the contact hole formed in the planarizing film 14, and thereafter the resultant formed film may be patterned by means of photolithography and etching to form the first electrode 21. After the formation of the first electrode 21, the element separation film 22 having an opening may be formed on the first electrode 21. Subsequently, the organic layer 23 may be formed in the opening of the element separation film 22. The organic layer 23 may be provided on the element separation film 22. The organic layer 23 may be formed using either a vapor-deposition method or an application method such as an ink-jet method.

After the formation of the organic layer 23, the electrically conductive film 24M may be formed across the entire surface of the first substrate 11 using a sputtering method, for example, as illustrated in FIG. 7A (step S202). The electrically conductive film 24M corresponds to a specific but non-limiting example of a “first electrically conductive film” according to one embodiment of the disclosure. The electrically conductive film 24M may be a film made of the constituent material of the second electrode 24, and may be configured by a light-transmissive electrically conductive material, for example. In this example, the electrically conductive film 24M may be formed across the entire surface of each of the display region 1A and the peripheral region 1B without using an area mask. This makes it possible to reduce a cost caused by the area mask.

After the formation of the electrically conductive film 24M, a protective material film 25M may be formed across the entire surface of the first substrate 11 using a CVD method, for example, as illustrated in FIG. 7B (step S203). The protective material film 25M may be a film made of the constituent material of the protective film 25, and may be configured by an inorganic insulating material, for example. The protective material film 25M may be formed on the entire surface of the electrically conductive film 24M.

After the formation of the protective material film 25M, the layers formed on the first substrate 11 may be sealed by the second substrate 31 as illustrated in FIG. 7C (step S204). In a specific but non-limiting example, the second substrate 31 may be joined onto the protective material film 25M with the filling layer 33 interposed therebetween, and the sealing section 34 may be formed on the periphery of the second substrate 31. For example, the color filter layer 32 may be formed in advance on the second substrate 31. The filling layer 33 and the sealing section 34 may be formed between the first substrate 11 and the second substrate 31, and thereafter the first substrate 11 may be cut into pieces having a predetermined size (step S205).

Next, the protective material film 25M over the terminal region 14T may be removed by etching to form the protective film 25 as illustrated in FIG. 7D (step S206). The etching of the protective material film 25M may be performed, for example, using the second substrate 31 as a mask. That is, the end part 25E of the protective film 25 may be formed at a location substantially overlapped by an end part of the second substrate 31 in a plan view. The etching of the protective material film 25M may be performed by means of reactive ion etching (RIE), for example.

After the formation of the protective film 25 from the protective material film 25M, the electrically conductive film 24M at least over the terminal region 14T may be removed by etching (step S207). Removing a portion of the electrically conductive film 24M in the peripheral region 1B in this manner allows the second electrode 24 to be formed. The etching of the electrically conductive film 24M may be performed, for example, using the protective film 25 as a mask. This allows the end part of the second electrode 24 to be formed at the location overlapped by the end part 25E of the protective film 25 in a plan view, thus allowing the end part of the second electrode 24 to be disposed under the end part 25E of the protective film 25. The etching of the electrically conductive film 24M may be performed by means of wet etching or dry etching, for example. When the electrically conductive film 24M is configured, for example, by silver (Ag) or zinc oxide (ZnO), for example, phosphoric, nitric, and acetic acid (i.e., a mixed solution of phosphoric acid, nitric acid, and acetic acid) may be used as an etchant. When the electrically conductive film 24M is configured, for example, by zinc oxide (ZnO) or indium oxide (In₂O₃), for example, oxalic acid may be used as an etchant. When the electrically conductive film 24M is configured, for example, by aluminum oxide (Al₂O₃), indium oxide (In₂O₃), stannic oxide (SnO₂), gallium oxide (Ga₂O₃), or niobium oxide (Nb₂O₅), for example, hydrofluoric acid may be used as an etchant. When the electrically conductive film 24M is configured, for example, by aluminum oxide (Al₂O₃) or zinc oxide (ZnO), for example, potassium hydroxide may be used as an etchant. When the electrically conductive film 24M is configured, for example, by silver (Ag), for example, nitric acid may be used as an etchant. When the electrically conductive film 24M is configured, for example, by titanium oxide (TiO₂), for example, a mixed solution of phosphoric acid and hydrogen peroxide solution may be used as an etchant. When the electrically conductive film 24M is configured, for example, by niobium oxide (Nb₂O₅), for example, a mixed solution of sulfuric acid and hydrochloric acid may be used as an etchant. When the electrically conductive film 24M is configured, for example, by silicon oxide (SiO₂), for example, a mixed solution of nitric acid and hydrofluoric acid or a mixed solution of sulfuric acid and hydrogen peroxide solution may be used as an etchant. A mixed solution of hydrochloric acid and nitric acid (i.e., aqua regia-based solution) may also be used as an etchant. In the present example embodiment, the second electrode 24 having a desired shape is formed by etching the electrically conductive film 24M at least over the terminal region 14T in this manner, thus making it possible to form the electrically conductive film 24M without using an area mask.

The display unit 1 is manufactured through the processes as described above.

### Workings and Effects

In the display unit 1 according to the present example embodiment, a selection pulse may be supplied to the switching transistor WsTr of each of the pixels P from the scanning line driver 3 to select a pixel P. A signal voltage corresponding to an image signal supplied from the signal line driver 4 may be supplied to the selected pixel P, and may be stored in the storage capacitor Cs. The driving transistor DsTr may be subjected to ON/OFF control in response to the signal stored by the storage capacitor Cs, and a drive current may be flowed into the organic EL element 20. This allows for generation of light emission through recombination of holes and electrons in the organic EL element 20, i.e., in the light-emitting layer of the organic layer 23. The light may be extracted, for example, through the second electrode 24, the protective film 25, the filling layer 33, the color filter layer 32, and the second substrate 31. This causes red light, green light, and blue light to be emitted from the respective pixels P, i.e., the pixels pr, pg, and pb, respectively. Additive color mixture of the color beams allows color image display to be performed.

In the present example embodiment, the electrically conductive film 24M may be formed without using an area mask, and thereafter the electrically conductive film 24M is etched to thereby form the second electrode 24. The etching of the electrically conductive film 24M may be performed, for example, using the protective film 25 as a mask, thus allowing the second electrode 24 to be disposed under the end part 25E of the protective film 25. The display unit 1 having such a configuration makes it possible to reduce a cost caused by the use of the area mask. This is described below.

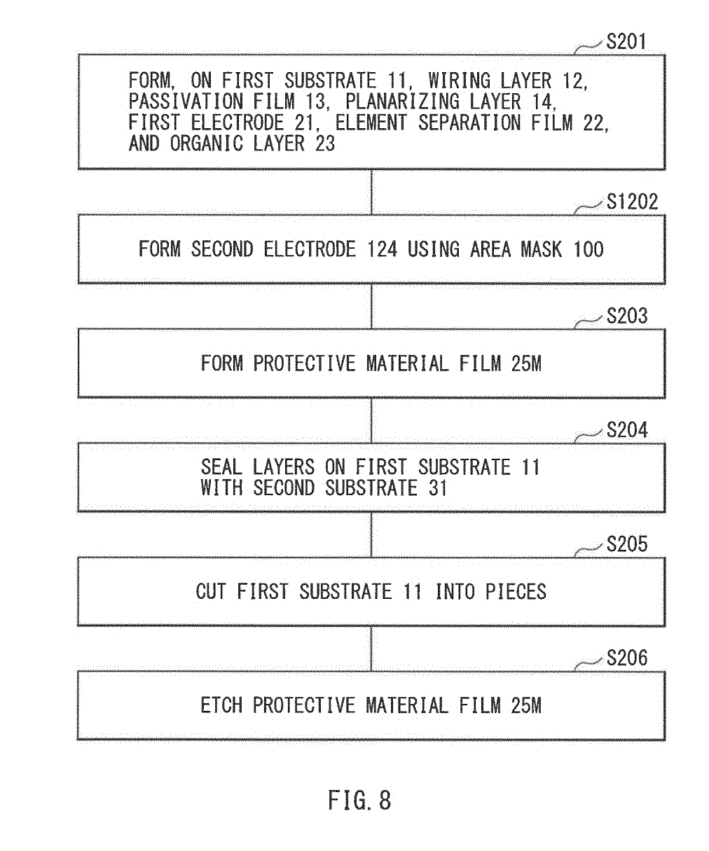

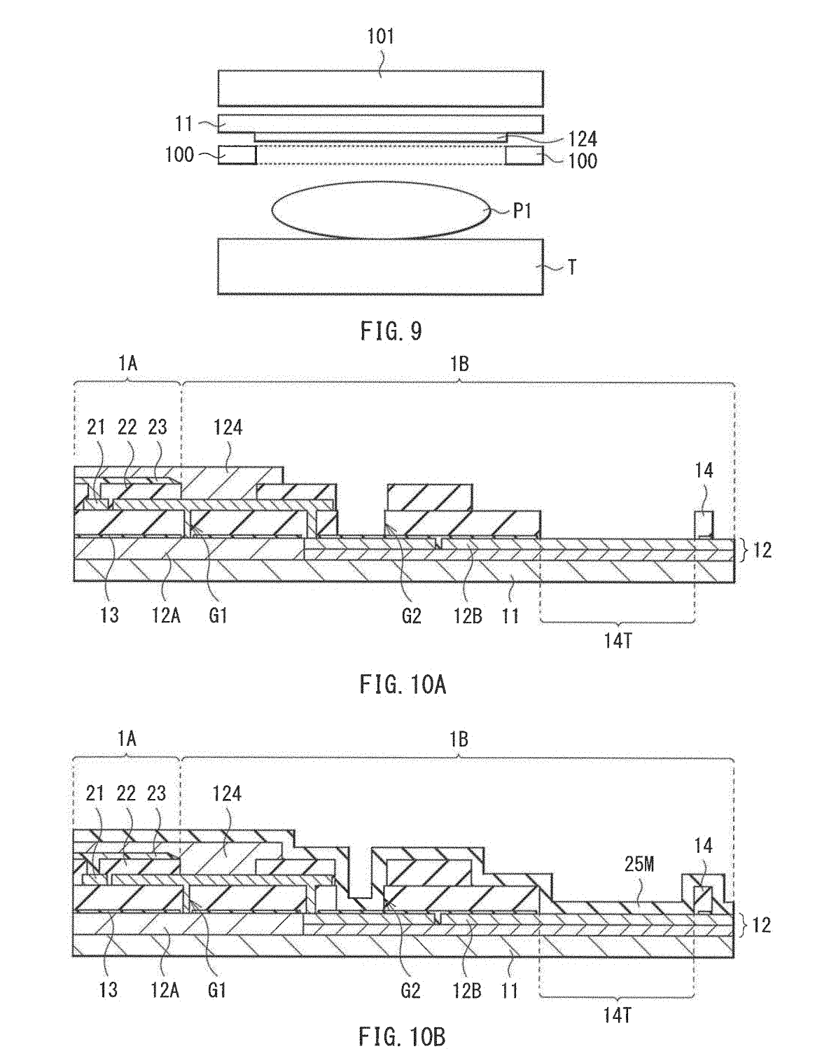

FIG. 8 illustrates manufacturing processes of a display unit according to a comparative example. In this method of manufacturing the display unit, after formation of the organic layer 23, a second electrode, i.e., a second electrode 124 is formed by means of a sputtering method using an area mask, i.e., an area mask 100 in FIG. 9 described later (step S1202).

Description is given of the process of step S1202 with reference to FIGS. 9 and 10A. FIG. 9 schematically illustrates the process of the sputtering method using the area mask 100. FIG. 10A illustrates a configuration of the second electrode 124 formed using the area mask 100. The area mask 100 is a metal mask, for example. The area mask 100 has an opening in the display region 1A and the peripheral region 1B near the display region 1A, and covers the terminal region 14T of the first substrate 11. The area mask 100 is fixed by a mask-fixing member 101 disposed on a rear surface of the first substrate 11 (i.e., a surface opposite to the surface where the second electrode 124 is formed). A magnet, for example, is used for the mask-fixing member 101. After the first substrate 11 is caused to face a target T, plasma pl is generated to cause a material of the target T to adhere to the opening of the area mask 100. This makes it possible to form the second electrode 124 without causing the material of the target T to adhere to the terminal region 14T.

After the formation of the second electrode 124, the protective material film 25M is formed across the entire area of the first substrate 11 as illustrated in FIG. 10B (step S203). The protective material film 25M is formed to cover an end part of the second electrode 124 having been formed using the area mask 100. After the formation of the protective material film 25M, the second substrate 31 is joined to the first substrate 11, and the organic EL element 20 is sealed therebetween (step S204). Subsequently, cutting of the first substrate 11 (step S205) and etching of the protective material film 25M (step S206) are performed in this order to manufacture a display unit.

In such a manufacturing method of the display unit, the second electrode 124 is formed using the area mask 100, thus making it unnecessary to use the process of removing an electrically conductive film over the terminal region 14T by means of etching (as in step S207 in FIG. 6, for example). However, the use of the area mask 100 may cause possible increase in manufacturing costs. Specifically, there are the following reasons. The first reason lies in expenses related to the area mask 100 and attached equipment such as the mask-fixing member 101. In a case where the first substrate 11 is increased in size, the weight of the area mask 100 is increased, and the expenses related to the area mask 100 itself are also increased. In addition, expenses of increasing the size of a sputtering apparatus is also necessary. The second reason lies in lowering of yield caused by adhesion of particles generated due to the area mask 100 to the first substrate 11. The lowering of yield also becomes a cause of an increased cost in association with the use of the area mask 100. For example, the number of the particles adhered to the first substrate 11 due to the area mask 100 is 10,000 or more, and there are still 4,000 or more particles even after washing of the area mask 100. Further, the washing of the area mask 100 further increases the cost. Frequent replacement of the area mask 100 may reduce the number of the particles to be adhered to the first substrate 11; however, also in this case, the cost is increased.

Meanwhile, in the present example embodiment, the electrically conductive film 24M may be formed without using an area mask, and the electrically conductive film 24M may be etched, thereby forming the second electrode 24 having a desired shape. Accordingly, no expenses related to the area mask and its attached equipment are generated. Further, the lowering of yield caused by adhesion of particles is also suppressed. Hence, it is possible to reduce the cost caused by the use of the area mask.

As described above, in the display unit 1, the second electrode 24 may be formed by etching the electrically conductive film 24M, thus making it possible to form the electrically conductive film 24M without using the area mask. Hence, it is possible to reduce the cost caused by the use of the area mask and thus to reduce the manufacturing costs.

Moreover, the first groove G1 and the second groove G2 may be provided in the planarizing film 14 including the organic insulating material in the peripheral region 1B, thus making it possible to suppress moisture ingress into the display region 1A via the planarizing film 14. Hence, it is possible to suppress lowering of reliability caused by the moisture ingress.

Description is given below of modification examples of the present example embodiment. In the following description, the same components as those of the foregoing example embodiment are denoted by the same reference numerals, and description thereof is omitted where appropriate.

### Modification Example 1

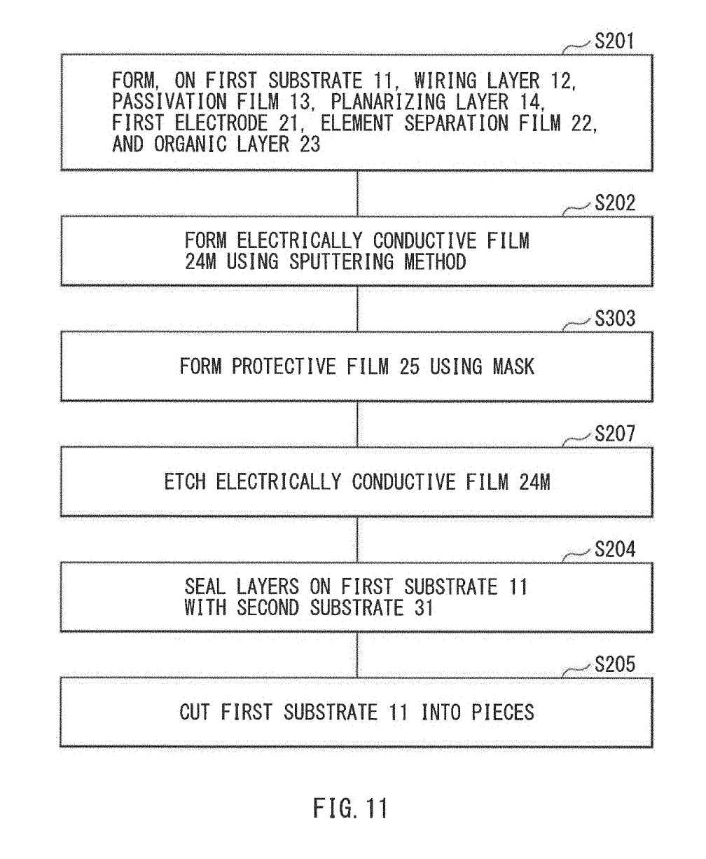

The display unit 1 may be manufactured through processes illustrated in FIG. 11 (Modification Example 1). This manufacturing method may involve using a mask to form the protective film 25 (step S303). Except this point, the manufacturing method of the display unit 1 according to Modification Example 1 is substantially the same as the manufacturing method of the display unit 1 described in the foregoing example embodiment, and the workings and effects thereof are also similar.

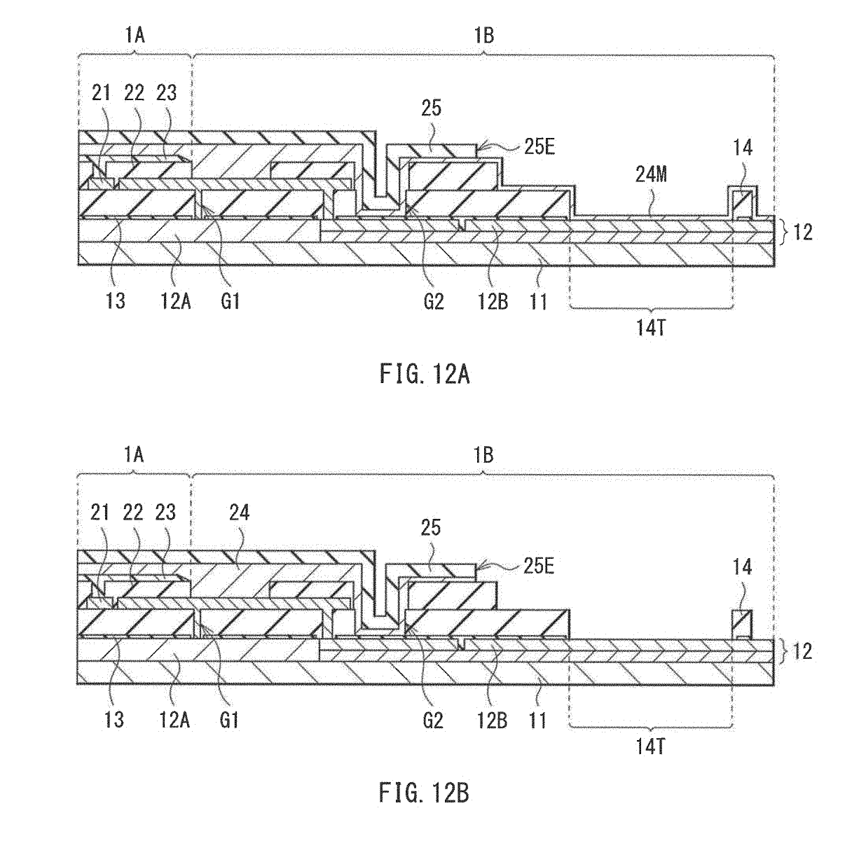

FIG. 12A illustrates the protective film 25 formed using a mask. Covering a part including the terminal region 14T with the mask makes it possible to form the protective film 25 in a region other than the part covered with the mask. In this step S303, the end part 25E of the protective film 25 may be formed.

After the formation of the protective film 25, as illustrated in FIG. 12B, for example, the electrically conductive film 24M may be etched using the protective film 25 as a mask (step S207). This may form the second electrode 24. After the formation of the second electrode 24, the display unit 1 may be manufactured through the sealing process (step S204) and the process of cutting the first substrate 11 (step S205).

In this manner, the mask may be used to form the protective film 25 (step S303) instead of the process of forming the protective material film 25M (step S203 in FIG. 6). This makes it possible to perform etching of the electrically conductive film 24M using the protective film 25 as the mask before cutting the first substrate 11 (step S205). In addition, similarly to the description in the foregoing example embodiment, the formation of the electrically conductive film 24M without using the area mask (step S202) makes it possible to reduce the cost caused by the use of the area mask. The mask to be used in forming the protective film 25 (step S303) is different from the area mask 100 to be used in forming the second electrode 124 described in the foregoing comparative example.

### Modification Example 2

The second electrode 24 may have a stacked structure (Modification Example 2).

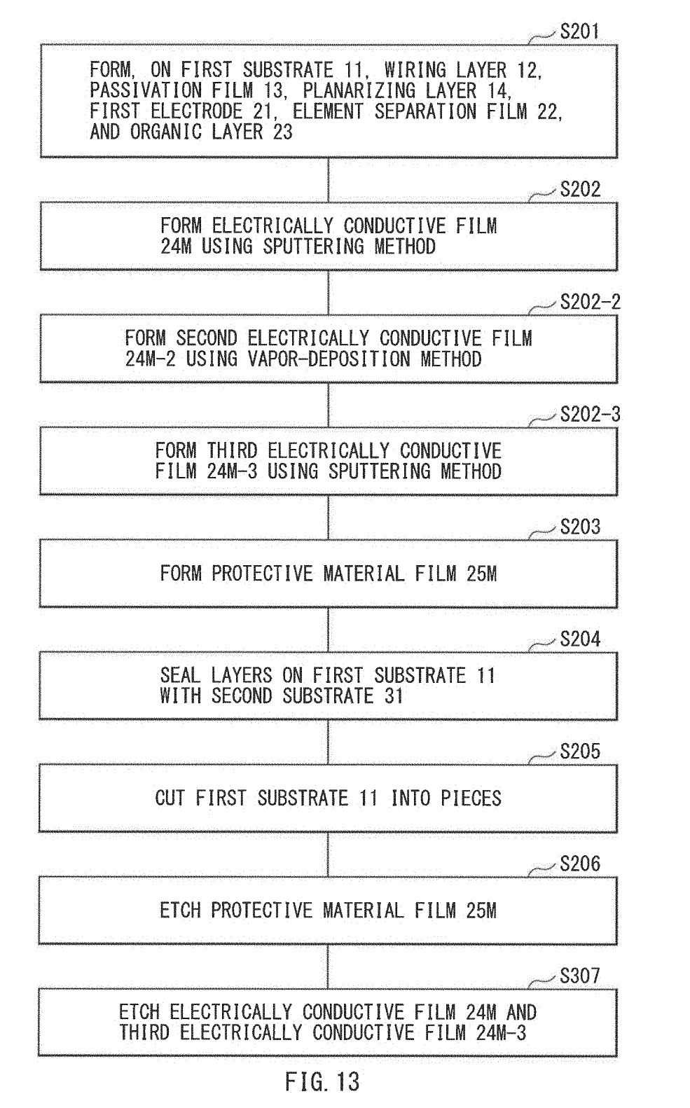

In a manufacturing method of the display unit 1 illustrated in FIG. 13, a plurality of electrically conductive films (i.e., the electrically conductive film 24M, a second electrically conductive film 24M-2, and a third electrically conductive film 24M-3) may be stacked to form the second electrode 24. In this manner, after the formation of the electrically conductive film 24M using the sputtering method (step S202), the second electrically conductive film 24M-2 may be formed using a vapor deposition method (step S202-2), and thereafter the third electrically conductive film 24M-3 may be further formed using the sputtering method (step S202-3). The second electrically conductive film 24M-2 may be formed using a mask, for example, and the third electrically conductive film 24M-3 may be formed across the entire surface of the first substrate 11 without using a mask similarly to the electrically conductive film 24M.

After the formation of the third electrically conductive film 24M-3, steps S203 to S206 may be performed similarly to the description in the foregoing example embodiment. Thereafter, the electrically conductive film 24M and the third electrically conductive film 24M-3 may be each etched (S307) to thereby form the second electrode 24 having the stacked structure.

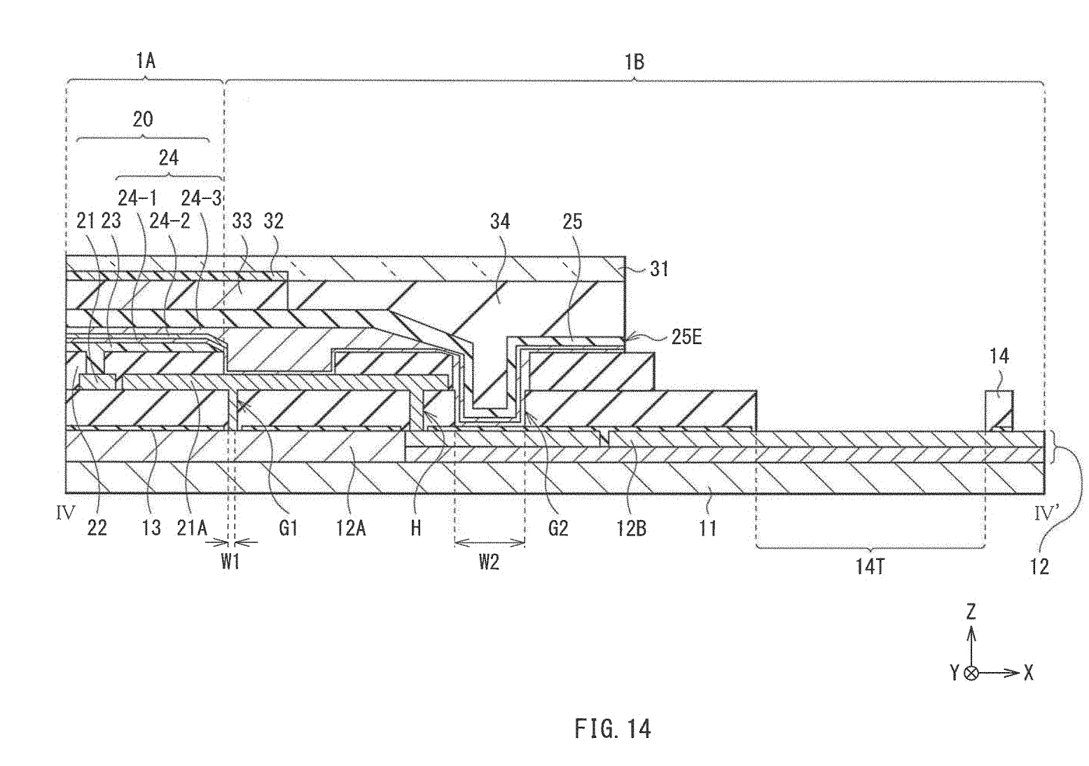

FIG. 14 illustrates a configuration of the display unit 1 including the second electrode 24 having the stacked structure. As illustrated, in the second electrode 24 having the stacked structure (i.e., the electrically conductive films 24-1, 24-2, and 24-3), positions of respective end parts of the electrically conductive films may differ from one another. For example, the end part of the electrically conductive film (the electrically conductive film 24-2) formed using the mask may be positioned closer to the display region 1A than the end part of each of the electrically conductive films (the electrically conductive films 24-1 and 24-3) formed through the film-forming and the etching. The electrically conductive film (the electrically conductive film 24-2) formed using the mask may be provided, for example, inside the second groove G2. In other words, the end part of the electrically conductive film 24-2 may be provided inside the second groove G2.

The electrically conductive film 24M, the second electrically conductive film 24M-2, and the third electrically conductive film 24M-3 may be formed in a different order from the order described in the above-described example. The second electrically conductive film 24M-2 may be formed using the sputtering method similarly to the electrically conductive films 24M and the third electrically conductive film 24M-3. At this occasion, the second electrically conductive film 24M-2 may be formed across the entire surface of the first substrate 11 without using the mask. In an alternative embodiment, the third electrically conductive film 24M-3 may be formed using the vapor-deposition method. For example, after the formation of the electrically conductive film 24M, the sputtering method may be used to form the second electrically conductive film 24M-2, and thereafter the vapor-deposition method may be used to form the third electrically conductive film 24M-3. Two electrically conductive films may be stacked to form the second electrode 24. In an alternative embodiment, four or more electrically conductive films may be stacked to form the second electrode 24. The sputtering method may be used for formation of all of the plurality of electrically conductive films. In an alternative embodiment, the vapor-deposition method may be used for formation of a portion of the plurality of electrically conductive films.

As described above, the plurality of electrically conductive films (i.e., the electrically conductive film 24M, the second electrically conductive film 24M-2, and the third electrically conductive film 24M-3) may be stacked to form the second electrode 24. In this case, similarly to the description in the foregoing example embodiment, the electrically conductive film 24M and the third electrically conductive film 24M-3 may be formed without using the area mask (steps S202 and S202-3), thus making it possible to reduce the cost caused by the use of the area mask.

### Application Example

### [Block Configuration Example of Display Unit 1]

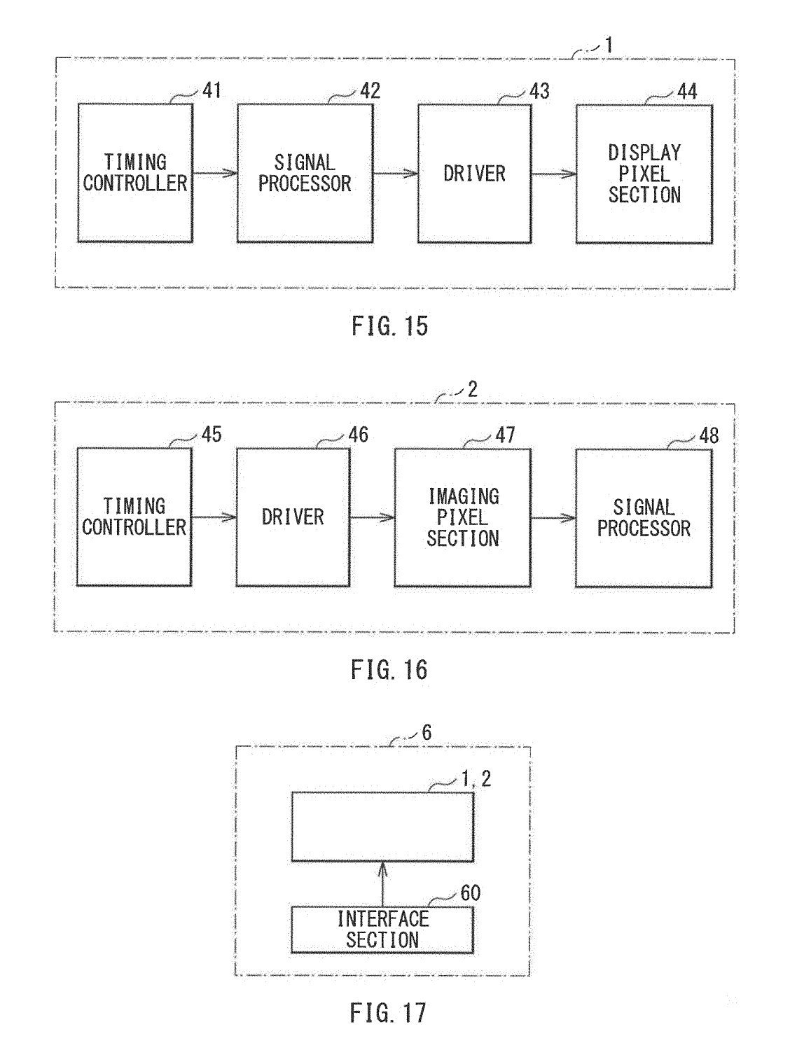

FIG. 15 is a block diagram schematically illustrating an example outline configuration of the display unit 1 according to the foregoing example embodiment and Modification Examples 1 and 2 (hereinafter, referred to as the foregoing example embodiment, etc.). The display unit 1 may display an image on the basis of an image signal inputted from an external device or an image signal generated inside. The display unit 1 may be applied not only to the organic EL display as described above but also to a liquid crystal display, for example. The display unit 1 may include, for example, a timing controller 41, a signal processor 42, a driver 43, and a display pixel section 44.

The timing controller 41 may include a timing generator that generates various timing signals, i.e., control signals. On the basis of these various timing signals, the timing controller 41 may perform a drive control of the signal processor 42, for example.

The signal processor 42 may perform, for example, a predetermined compensation on a digital image signal inputted from an external device, and may output, to the driver 43, an image signal thus obtained.

The driver 43 may include, for example, a scanning line drive circuit and a signal line drive circuit, and may drive each pixel of the display pixel section 44 through various control lines.

The display pixel section 44 may include, for example, a display element such as the organic EL element 20 and a liquid crystal display element, and a pixel circuit that drives the display element on a pixel basis.

### [Block Configuration Example of Imaging Unit 2]

In the foregoing example embodiment, etc., description has been given by exemplifying the display unit 1 as a specific but non-limiting example of the electronic device according to the disclosure; however, the electronic device according to the disclosure may be configured by a unit other than the display unit 1 (such as an imaging unit).

FIG. 16 is a block diagram schematically illustrating an example outline configuration of an imaging unit 2 as the electronic device. The imaging unit 2 may be a solid-state imaging unit that obtains an image, for example, as an electric signal. The imaging unit 2 may be configured by, for example, a charge coupled device (CCD) image sensor or a complementary metal oxide semiconductor (CMOS) image sensor. The imaging unit 2 may include, for example, a timing controller 45, a driver 46, an imaging pixel section 47, and a signal processor 48.

The timing controller 45 may include a timing generator that generates various timing signals, i.e., control signals. On the basis of these various timing signals, the timing controller 45 may perform a drive control of the driver 46.

The driver 46 may include, for example, a row selection circuit, an analog-to-digital (AD) conversion circuit, and a horizontal transfer scanning circuit. The driver 46 may perform driving to read a signal from each pixel of the imaging pixel section 47 through various control lines.

The imaging pixel section 47 may include, for example, an imaging element, i.e., a photoelectric conversion element such as a photodiode, and a pixel circuit for reading of a signal. Non-limiting examples of such an imaging element may include, in addition to an element that detects visible light, an element that detects, directly or indirectly, infrared light, ultraviolet light, and a radioactive ray (such as an X-ray).

The signal processor 48 may apply various types of signal processing to the signal obtained from the imaging pixel section 47.

### [Configuration Example of Electronic Apparatus]

Any of the above-described electronic devices (such as the display unit 1 and the imaging unit 2) may be applied to various types of electronic apparatuses.

FIG. 17 is a block diagram illustrating an example of application to an electronic apparatus, i.e., an electronic apparatus 6 including the display unit 1 illustrated in FIG. 15 or the imaging unit 2 illustrated in FIG. 16. Specific but non-limiting examples of the electronic apparatus 6 may include a television, a personal computer (PC), a smartphone, a tablet PC, a mobile phone, a digital still camera, and a digital video camera.

The electronic apparatus 6 may include, for example, any of the above-described display unit 1 and the imaging unit 2, and an interface section 60. The interface section 60 may be an input section that receives various signals and a power supply, for example, from an external device. The interface section 60 may include a user interface such as a touch panel, a keyboard, and operation buttons, for example.

Although description has been given hereinabove with reference to the example embodiment, the technology is not limited thereto, but may be modified in a wide variety of ways. For example, factors such as a material and a thickness of each layer, and a film-forming method as well as a film-forming condition exemplified in the foregoing example embodiment, etc. are illustrative and non-limiting. Any other material, any other thickness, any other film-forming method, any other film-forming condition, and any other factor may be adopted besides those described above.

It is sufficient that the organic layer 23 may include at least the light-emitting layer. For example, the organic layer 23 may be configured only by the light-emitting layer.

Furthermore, in the foregoing example embodiment, description has been given of the case of the active matrix display unit; however, the disclosure may also be applied to a passive matrix display unit. Moreover, the configuration of the pixel circuit PXLC for active matrix driving is not limited to that described in the foregoing example embodiment; a capacitor element or a transistor may also be added as necessary. In this case, a necessary drive circuit may also be added, in addition to the scanning line driver 3, the signal line driver 4, and the power line driver 5, depending on alteration of the pixel circuit PXLC.

The effects described in the foregoing example embodiment are mere examples. The effects according to an embodiment of the disclosure may be other effects, or may further include other effects in addition to the effects described hereinabove.

Note that the technology may also have the following configurations.

(1)
An electronic device including:
a substrate including an element region;
a first electrode provided in the element region on the substrate;
a second electrode that faces the first electrode and is provided across from the element region to an outside of the element region, the second electrode including a first electrically conductive film; and
a protective film that covers the first electrically conductive film, the protective film having an end part under which the first electrically conductive film is disposed.
   (2)
The electronic device according to (1), further including:
a wiring layer provided between the substrate and the first electrode; and
a planarizing film that is provided between the wiring layer and the first electrode and extends from the element region to the outside of the element region, the planarizing film including, outside the element region, a first groove and a second groove outside the first groove.
   (3)
The electronic device according to (2), in which the first electrically conductive film is provided in the second groove of the planarizing film and extends to an outside of the second groove.
   (4)
The electronic device according to (3), in which
the second electrode further includes a second electrically conductive film, and
the second electrically conductive film has an end part that is provided inside the second groove.
   (5)
The electronic device according to any one of (1) to (4), further including a functional layer provided between the first electrode and the second electrode.
   (6)
The electronic device according to (5), in which the functional layer includes an organic light-emitting material.
   (7)
The electronic device according to any one of (1) to (6), in which the second electrode includes a light-transmissive electrically conductive material.
   (8)
A method of manufacturing an electronic device, the method including:
forming a first electrode in an element region on a substrate;
forming a first electrically conductive film that faces the first electrode and is provided across from the element region to an outside of the element region;
forming a protective film that covers the first electrically conductive film;
etching a portion of the first electrically conductive film provided outside the element region after the formation of the protective film; and
forming a second electrode including the etched first electrically conductive film.
   (9)
The method of manufacturing the electronic device according to (8), in which the etching of the first electrically conductive film involves using the protective film as a mask.
   (10)
The method of manufacturing the electronic device according to (8) or (9), in which the forming of the first electrically conductive film involves using a sputtering method.
   (11)
The method of manufacturing the electronic device according to any one of (8) to (10), in which the forming of the first electrically conductive film is performed across an entire surface of the substrate.
   (12)
The method of manufacturing the electronic device according to any one of (8) to (11), further including:
forming a second electrically conductive film using a vapor-deposition method; and
forming the second electrode including the second electrically conductive film and the etched first electrically conductive film.
   (13)
The method of manufacturing the electronic device according to any one of (8) to (12), further including:
forming a third electrically conductive film across the entire surface of the substrate using a sputtering method; and
forming the second electrode by etching a portion of each of the first electrically conductive film and the third electrically conductive film.
   (14)
The method of manufacturing the electronic device according to any one of (8) to (13), in which the forming of the protective film involves using a mask.

The method of manufacturing the electronic device according to one embodiment of the technology includes etching a portion of the first electrically conductive film, thus allowing the second electrode to be processed into a desired shape even when the first electrically conductive film is formed without using an area mask, for example.

In the electronic device according to one embodiment of the technology, the first electrically conductive film is disposed under the end part of the protective film. The first electrically conductive film is formed, for example, by etching the electrically conductive film after the formation of the end part of the protective film. The electronic device according to one embodiment of the technology is manufactured, for example, using the method of manufacturing the electronic device according to one embodiment of the technology.

According to the electronic device and the manufacturing method thereof according to respective embodiments of the technology, the second electrode including the etched first electrically conductive film is formed, thus enabling the first electrically conductive film to be formed without using the area mask. Hence, it becomes possible to reduce the cost caused by the use of the area mask and thus to reduce the manufacturing costs. Note that the effects described herein are not necessarily limitative, and may be any of the effects described in the disclosure.

Although the technology has been described in terms of exemplary embodiments, it is not limited thereto. It should be appreciated that variations may be made in the described embodiments by persons skilled in the art without departing from the scope of the technology as defined by the following claims. The limitations in the claims are to be interpreted broadly based on the language employed in the claims and not limited to examples described in this specification or during the prosecution of the application, and the examples are to be construed as non-exclusive. For example, in this technology, the term “preferably” or the like is non-exclusive and means “preferably”, but not limited to. The use of the terms first, second, etc. do not denote any order or importance, but rather the terms first, second, etc. are used to distinguish one element from another. The term “substantially” and its variations are defined as being largely but not necessarily wholly what is specified as understood by one of ordinary skill in the art. The term “about” as used herein can allow for a degree of variability in a value or range. Moreover, no element or component in this technology is intended to be dedicated to the public regardless of whether the element or component is explicitly recited in the following claims.

What is claimed is:

1. An electronic device comprising:
a substrate including an element region;
a first electrode provided in the element region on the substrate;
a second electrode that faces the first electrode and is provided across from the element region to an outside of the element region, the second electrode including a first electrically conductive film; and
a protective film that covers the first electrically conductive film, the protective film having an end part under which the first electrically conductive film is disposed.

2. The electronic device according to claim 1, further comprising:
a wiring layer provided between the substrate and the first electrode; and
a planarizing film that is provided between the wiring layer and the first electrode and extends from the element region to the outside of the element region, the planarizing film including, outside the element region, a first groove and a second groove outside the first groove.

3. The electronic device according to claim 2, wherein the first electrically conductive film is provided in the second groove of the planarizing film and extends to an outside of the second groove.

4. The electronic device according to claim 3, wherein
the second electrode further includes a second electrically conductive film, and
the second electrically conductive film has an end part that is provided inside the second groove.

5. The electronic device according to claim 1, further comprising a functional layer provided between the first electrode and the second electrode.

6. The electronic device according to claim 5, wherein the functional layer includes an organic light-emitting material.

7. The electronic device according to claim 1, wherein the second electrode includes a light-transmissive electrically conductive material.

8. A method of manufacturing an electronic device, the method comprising:
forming a first electrode in an element region on a substrate;
forming a first electrically conductive film that faces the first electrode and is provided across from the element region to an outside of the element region;
forming a protective film that covers the first electrically conductive film;
etching a portion of the first electrically conductive film provided outside the element region after the formation of the protective film; and
forming a second electrode including the etched first electrically conductive film.

9. The method of manufacturing the electronic device according to claim 8, wherein the etching of the first electrically conductive film involves using the protective film as a mask.

10. The method of manufacturing the electronic device according to claim 8, wherein the forming of the first electrically conductive film involves using a sputtering method.

11. The method of manufacturing the electronic device according to claim 8, wherein the forming of the first electrically conductive film is performed across an entire surface of the substrate.

12. The method of manufacturing the electronic device according to claim 8, further comprising:
forming a second electrically conductive film using a vapor-deposition method; and
forming the second electrode including the second electrically conductive film and the etched first electrically conductive film.

13. The method of manufacturing the electronic device according to claim 8, further comprising:
forming a third electrically conductive film across an entire surface of the substrate using a sputtering method; and
forming the second electrode by etching a portion of each of the first electrically conductive film and the third electrically conductive film.

14. The method of manufacturing the electronic device according to claim 8, wherein the forming of the protective film involves using a mask.
